(19) United States
(12) Patent Application Publication
(10) Pub. No.: US 2025/0266331 A1
(43) Pub. Date: Aug. 21, 2025

(54) SEMICONDUCTOR DEVICE

(71) Applicant: Rohm Co., Ltd., Kyoto-shi (JP)

(72) Inventor: Akinori NII, Kyoto-shi (JP)

(21) Appl. No.: 19/052,834

(22) Filed: Feb. 13, 2025

(30) Foreign Application Priority Data
Feb. 20, 2024 (JP) 2024-023528

(51) Int. Cl. H01L 23/495; H01L 23/00; H01L 23/31

(52) U.S. Cl. CPC H01L 23/49548; H01L 24/16; H01L 23/3121; H01L 23/49579; H01L 2224/16245

(57) ABSTRACT

A semiconductor device includes a conductive member, a semiconductor element, and a sealing resin. The conductive member includes a wiring portion, and a terminal portion connected to the wiring portion. The semiconductor element faces the wiring portion in a thickness direction and includes an electrode. The wiring portion includes a first portion overlapping with the terminal portion and a second portion not overlapping with the terminal portion as viewed in the thickness direction. The second portion includes a first area between a part overlapping with the electrode as viewed in the thickness direction and a part where the second portion is connected to the first portion. The first portion and the first area constitute a second area as viewed in the thickness direction. The ratio of the second area to the first wiring portion is 60% or less.

### TECHNICAL FIELD

This disclosure relates to a semiconductor device.

### BACKGROUND ART

Various configurations of semiconductor devices with semiconductor elements have been proposed. JP-A-2020-77694 discloses an example of a conventional semiconductor device. The conventional semiconductor device disclosed includes a lead and a semiconductor element. The lead includes a plurality of terminal portions. In the semiconductor device disclosed in JP-A-2020-77694, the semiconductor element is mounted on the lead by flip-chip mounting. The lead includes an obverse face facing one side of a thickness direction. The semiconductor element includes a plurality of electrodes provided on a side face facing the obverse face, and the plurality of electrodes are bonded to the obverse face of the lead via a bonding layer comprising, for example, solder. The lead is electrically connected to an internal circuit of the semiconductor element via at least one of the plurality of electrodes. In the semiconductor device disclosed in JP-A-2020-77694, an electrical current flows between the semiconductor element and the lead via the electrode. The lead is involved in the conduction path between the semiconductor element and a wiring board on which the semiconductor device is mounted. Semiconductor devices configured from such a way have room for improvement in their electrical characteristics.

### BRIEF DESCRIPTION OF THE DRAWINGS

FIG. 1 is a perspective view of a semiconductor device according to a first embodiment of the present disclosure.

FIG. 2 is a plan view of the semiconductor device according to the first embodiment of the present disclosure (the sealing resin is omitted).

FIG. 3 is a plan view of the semiconductor device according to the first embodiment of the present disclosure (the semiconductor element and the sealing resin are omitted).

FIG. 4 is a bottom view of the semiconductor device according to the first embodiment of the present disclosure.

FIG. 5 is a front view of the semiconductor device according to the first embodiment of the present disclosure.

FIG. 6 is a back view of the semiconductor device according to the first embodiment of the present disclosure.

FIG. 7 is a right-side view of the semiconductor device according to the first embodiment of the present disclosure.

FIG. 8 is a left-side view of the semiconductor device according to the first embodiment of the present disclosure.

FIG. 9 is a cross-sectional view taken along a line IX-IX in FIG. 3.

FIG. 10 is a cross-sectional view taken along a line X-X in FIG. 3.

FIG. 11 is a cross-sectional view taken along a line XI-XI in FIG. 3.

FIG. 12 is a cross-sectional view taken along a line XII-XII in FIG. 3.

FIG. 13 is a cross-sectional view taken along a line XIII-XIII in FIG. 3.

FIG. 14 is a partially enlarged view of FIG. 3.

FIG. 15 is a partially enlarged view of FIG. 9.

FIG. 16 is a plan view similar to FIG. 3, showing a semiconductor device according to a first variation of the first embodiment.

FIG. 17 is a cross-sectional view taken along a line XVII-XVII in FIG. 16.

FIG. 18 is a cross-sectional view taken along a line XVIII-XVIII in FIG. 16.

FIG. 19 is a partially enlarged view of FIG. 16.

FIG. 20 is a partially enlarged view of FIG. 17.

FIG. 21 is a plan view similar to FIG. 3, showing a semiconductor device according to a second variation of the first embodiment.

FIG. 22 is a cross-sectional view taken along a line XXII-XXII in FIG. 21.

FIG. 23 is a cross-sectional view taken along a line XXIII-XXIII in FIG. 21.

FIG. 24 is a partially enlarged view of FIG. 21.

FIG. 25 is a partially enlarged view of FIG. 22.

### DETAILED DESCRIPTION OF EMBODIMENTS

The following describes preferred embodiments of the present disclosure in detail with reference to the drawings.

In the present disclosure, the terms such as “first”, “second”, and “third” are used merely as labels and are not intended to impose ordinal requirements on the items to which these terms refer.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”. Also, the phrase “an object A (or the material thereof) contains a material C” includes “an object A (or the material thereof) is made of a material C” and “an object A (or the material thereof) is mainly composed of a material C”. Furthermore, in the description of the present disclosure, the expression “A surface A faces (a first side or a second side) in a direction B” is not limited to the situation where the angle of the surface A to the direction B is 90° and includes the situation where the surface A is inclined with respect to the direction B.

### First Embodiment

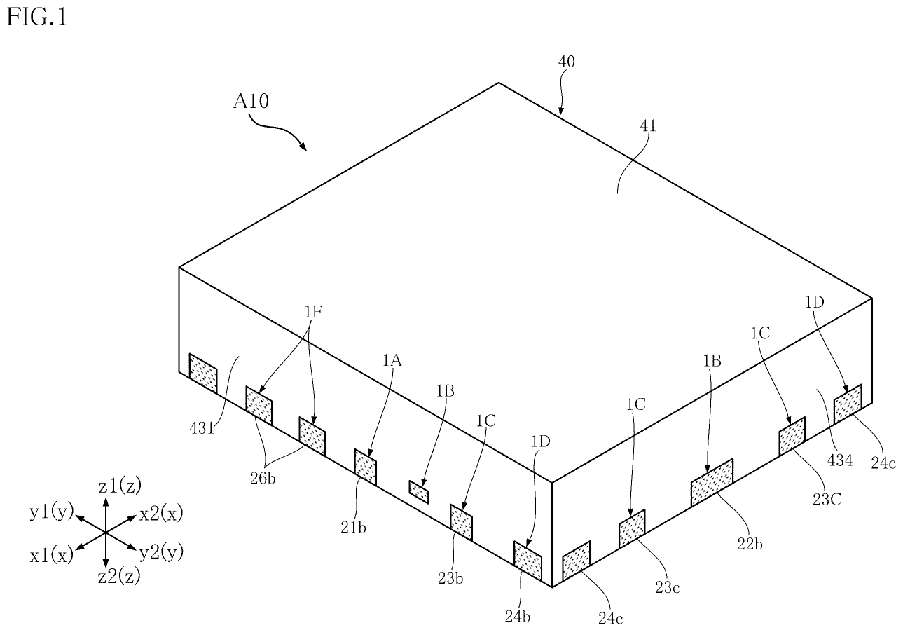

The semiconductor device of a first embodiment of the present disclosure will be described based on FIGS. 1 to 15. The semiconductor device A10 in the present embodiment includes a first conductive member 1A, a second conductive member 1B, a pair of third conductive members 1C, pluralities of conductive members 1D, 1E, 1F, a semiconductor element 3 and a sealing resin 4. The package format of the semiconductor device A10 is a QFN (Quad For Non-Lead Package). The package format of the semiconductor device A10 is not to QFN. The specific configuration of the limited semiconductor element 3 is not particularly limited, and the semiconductor element 3 is, for example, a flip-chip type LSI (Large Scale Integration).

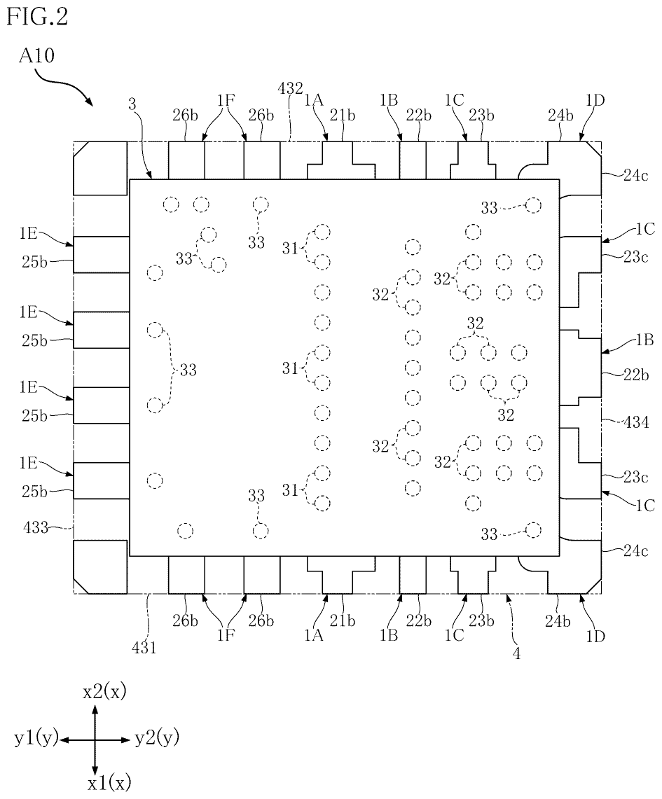

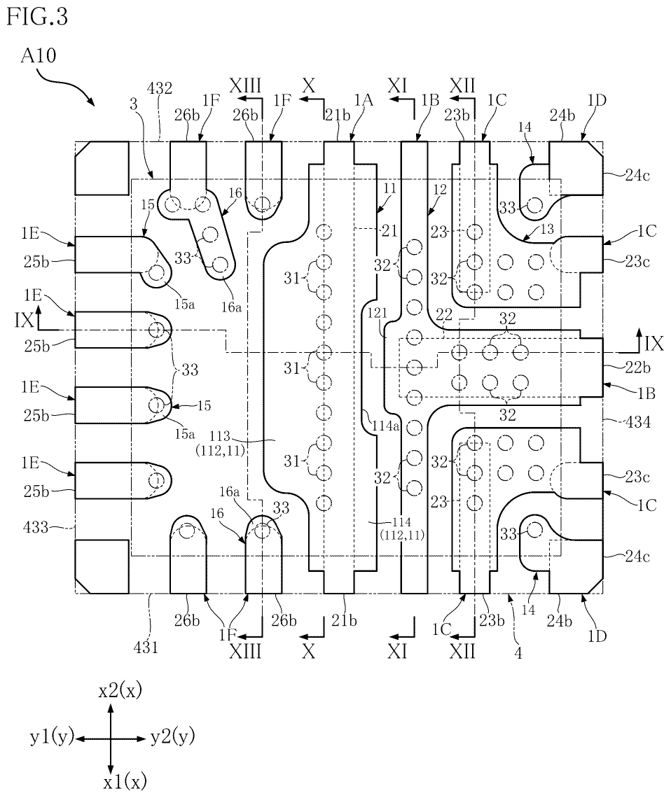

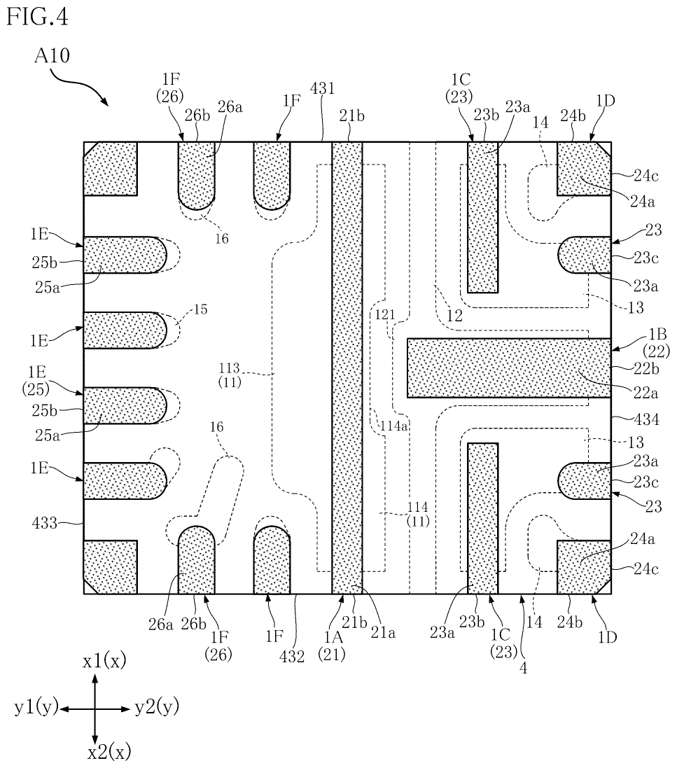

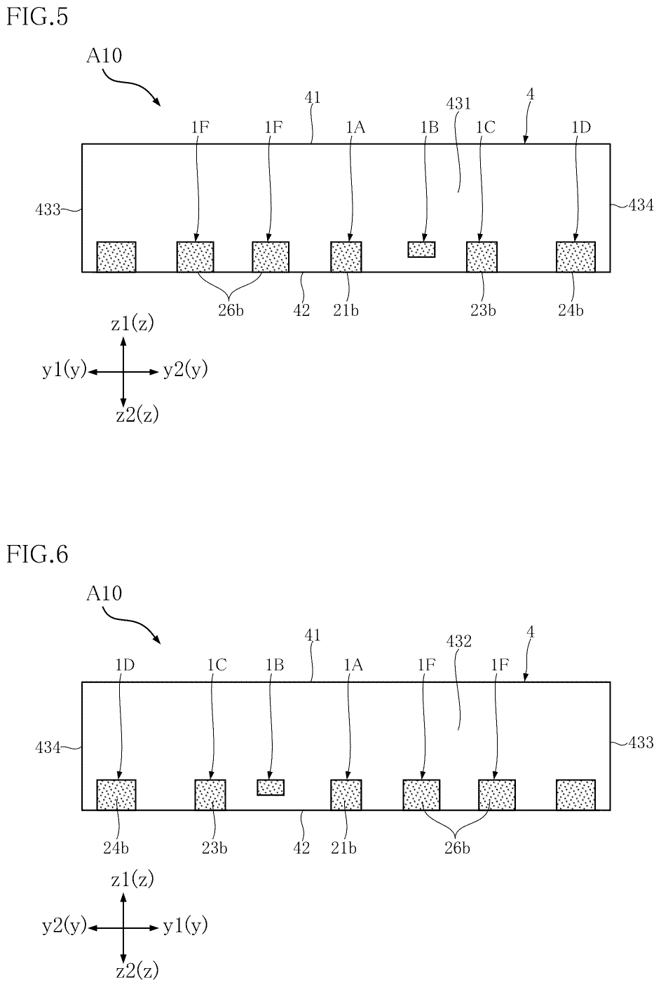

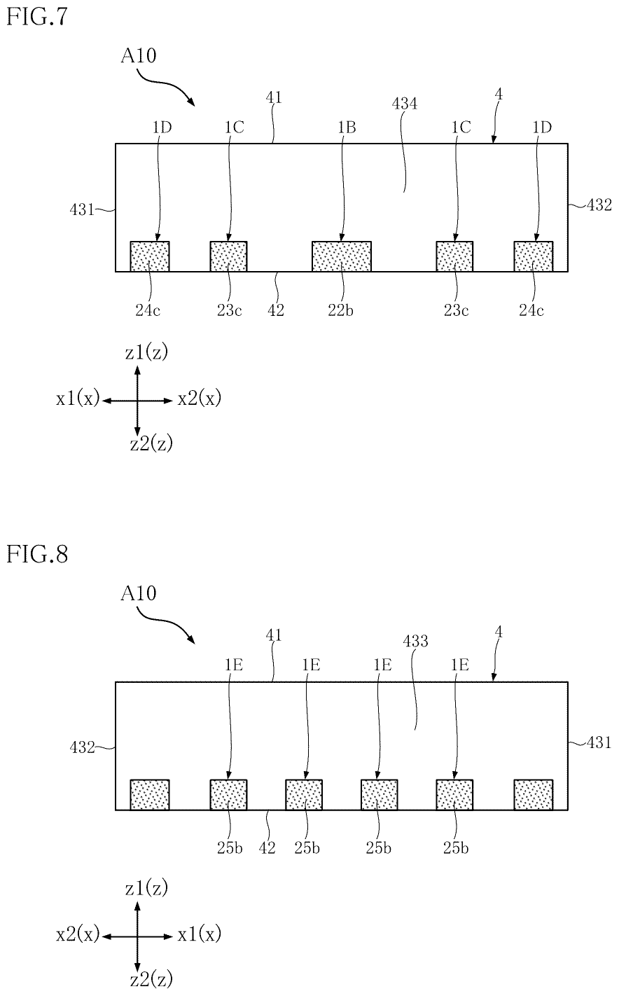

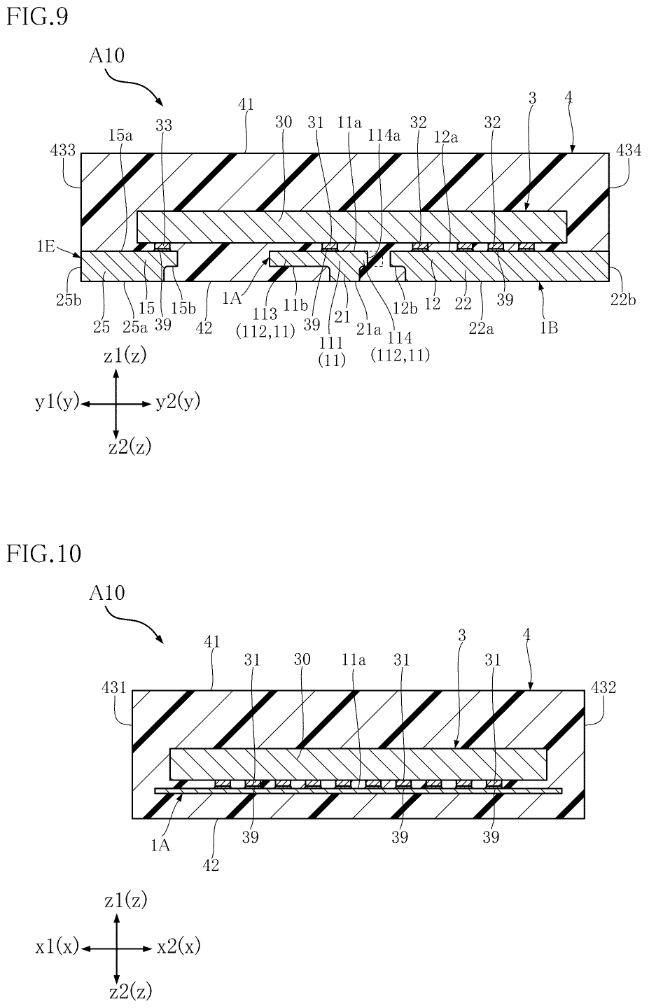

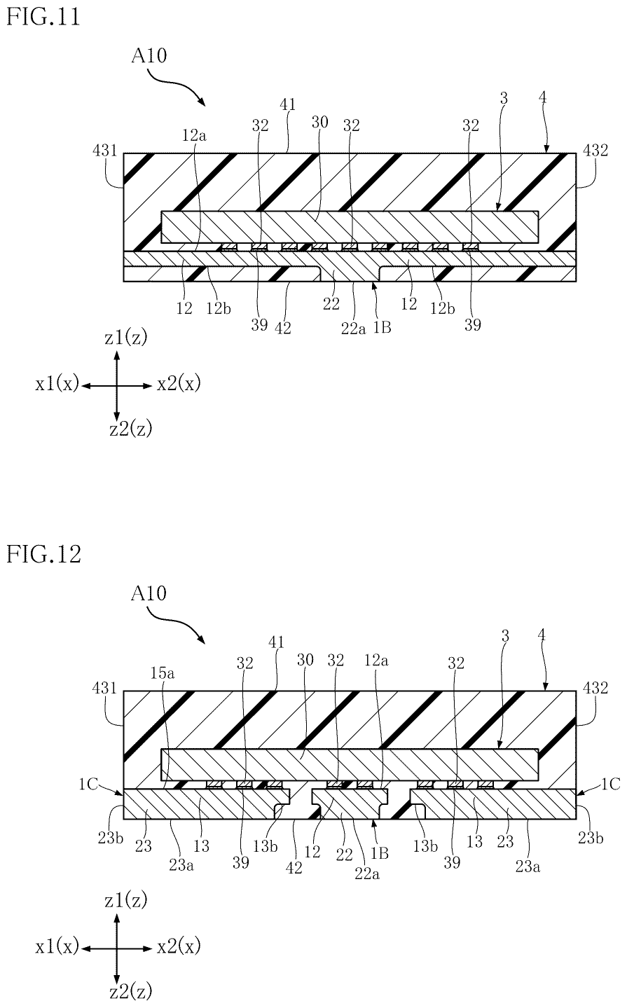

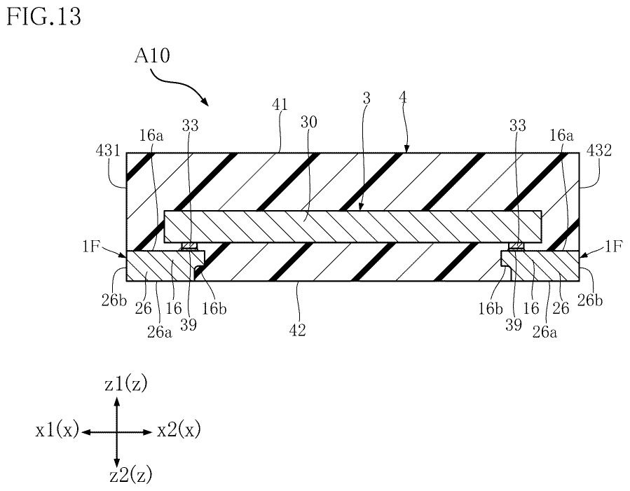

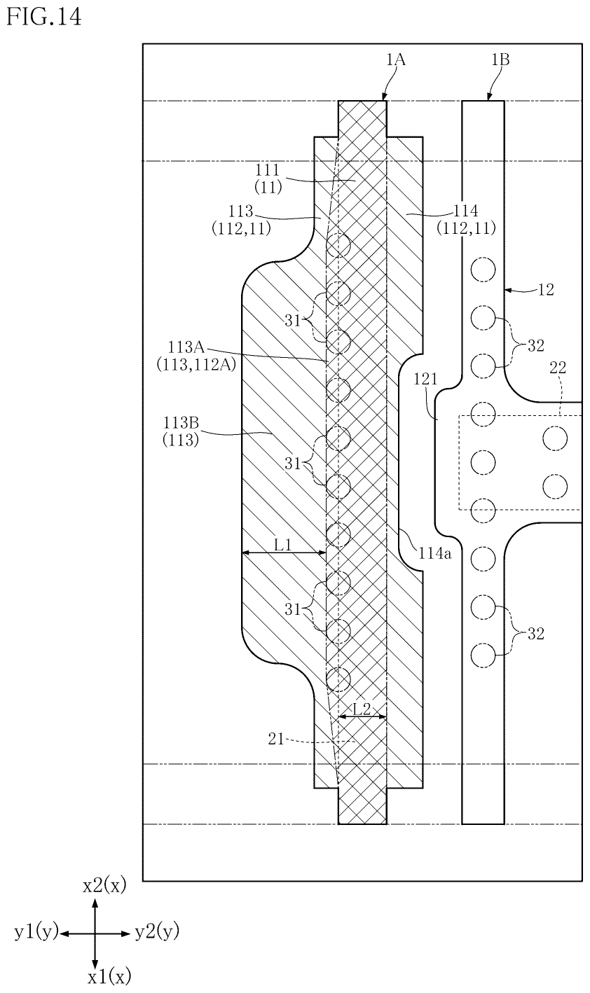

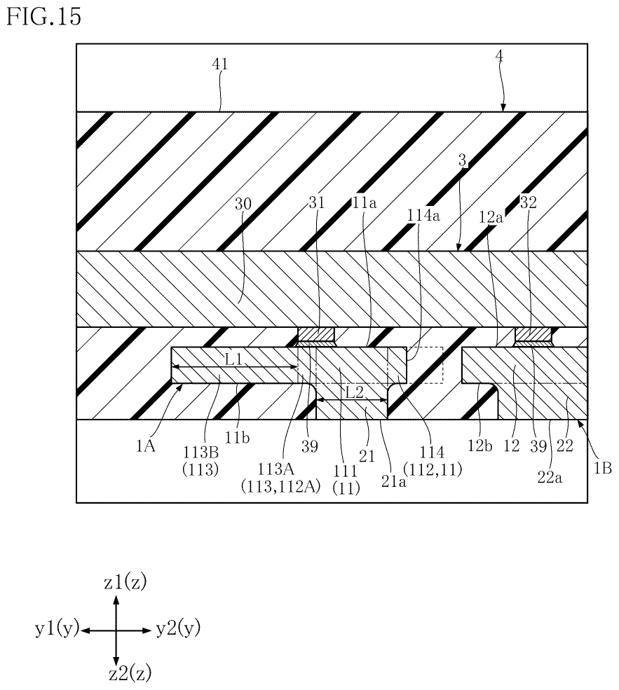

FIG. 1 is a perspective view of the semiconductor device A10. FIG. 2 is a plan view of the semiconductor device A10, with the sealing resin 4 transparent. FIG. 3 is a plan view of semiconductor device A10, in which the semiconductor element 3 and the sealing resin 4 are omitted. FIG. 4 is a bottom view of the semiconductor device A10. FIG. 5 is a front view of the semiconductor device A10. FIG. 6 is a back view of the semiconductor device A10. FIG. 7 is a right-side view of the semiconductor device A10. FIG. 8 is a left-side view of the semiconductor device A10. FIG. 9 is a cross-sectional view taken along a line IX-IX in FIG. 3. FIG. 10 is a cross-sectional view taken along a line X-X in FIG. 3. FIG. 11 is a cross-sectional view taken along a line XI-XI in FIG. 3. FIG. 12 is a cross-sectional view taken along a line XII-XII in FIG. 3. FIG. 13 is a cross-sectional view taken along a line XIII-XIII in FIG. 3. FIG. 14 is a partially enlarged view of FIG. 3. FIG. 15 is a partially enlarged view of FIG. 9. In FIG. 2, the omitted sealing resin 4 is indicated as an imaginary line (double-dotted line). In FIG. 3, the omitted semiconductor element 3 and sealing resin 4 are indicated as imaginary lines (two dotted lines), respectively.

In the following explanation, the thickness direction (the plan-view direction) of the semiconductor device (the first conductive member 1A) is referred to as a “thickness direction z”. A direction orthogonal to the thickness direction z is referred to as a “first direction x”. direction orthogonal to the thickness direction z and the first direction x is referred to as a “second direction y”.

In the explanation of the semiconductor device A10, one side of the first direction x is referred to as an “x1 side of the first direction x”, and the other side is referred to as an “x2 side of the first direction x”. One side of the second direction y is referred to as an “y1 side of the second direction y”, and the other side of the second direction y is referred to as an “y2 side of the second direction y”. One side of the thickness direction z is referred to as an “z1 side of the thickness direction z”, and the other side of the thickness direction z is referred to as an “z2 side of the thickness direction z”. Note that the terms such as “top”, “bottom”, “upward”, “downward”, “upper surface”, and “lower surface” are used to indicate the relative position between parts, etc., in the thickness direction z and do not necessarily define the relationship with respect to the direction of gravity.

The sealing resin 4 covers the first conductive member 1A, the second conductive member 1B, the pair of third conductive members 1C, a part of each of the pluralities of conductive members 1D, 1E, 1F, and the semiconductor element 3, as shown in FIGS. 1 to 3 and 9 to 13. The sealing resin 4 has electrical insulating properties. The constituent material of the sealing resin 4 is, for example, black epoxy resin. As viewed in the thickness direction z, the sealing resin 4 is rectangular.

As shown in FIGS. 5 to 8, the sealing resin 4 includes a resin obverse face 41, a resin reverse face 42, a first resin side face 431, a second resin side face 432, a third resin side face 433, and a fourth resin side face 434. The resin obverse face 41 and the resin reverse face 42 face opposite each other in the thickness direction z. The resin obverse face 41 faces the z1 side of the thickness direction Z. The resin reverse face 42 faces the z2 side of the thickness direction z. The first resin side face 431 and the second resin side face 432 face opposite each other in the first direction x. The first resin side face 431 faces the x1 side of the first direction x. The second resin side face 432 faces the x2 side of the first direction x. The third resin side face 433 and the fourth resin side face 434 face opposite each other in the second direction y. The third resin side face 433 faces the y1 side of the second direction y. The fourth resin side face 434 faces the y2 side of the second direction y.

The first conductive member 1A, the second conductive member 1B, the pair of third conductive members 1C, and the pluralities of conductive members 1D, 1E, 1F each carry a semiconductor element 3, as shown in FIGS. 9 to 13. These conductive members 1A to 1F provide, for example, a conductive path between the semiconductor element 3 and wiring substrates on which the semiconductor device A10 is mounted. The constituent materials of the conductive members 1A-1F include, for example, copper (Cu). The conductive members 1A-1F may be formed from the same lead frame.

As shown in FIG. 3, the first conductive member 1A is located on the center of the semiconductor device A10 in the second direction y. The first conductive member 1A includes a first wiring portion 11 and a first terminal portion 21, as shown in FIGS. 3, 4 and 9. The first wiring portion 11 extends in the first direction x as a whole. In the present embodiment, the first wiring portion 11 extends from the end on the x1 side of the first direction x to the end on the x2 side of the first direction x in the semiconductor device A10. The first wiring portion 11 includes a first obverse face 11a and a first intermediate face 11b. The first obverse face 11a faces the z1 side of the thickness direction z. The first obverse face 11a faces the semiconductor element 3 and supports the semiconductor element 3. The first intermediate face 11b is offset in the z2 side of the thickness direction z with respect to the first obverse face 11a. The first intermediate face 11b faces the opposite side of the first obverse face 11a (z2 side of the thickness direction z). The first obverse face 11a and the first intermediate face 11b are covered by the sealing resin 4. The first obverse face 11a, which supports the semiconductor element 3, may be plated with silver (Ag).

The first terminal portion 21 is connected to the first wiring portion 11 on the z2 side of the thickness direction Z. The first terminal portion 21 extends in the first direction x. The first terminal portion 21 extends from the end on the x1 side of the first direction x to the end on the x2 side of the first direction x in the semiconductor device A10. As viewed in the thickness direction z, the first terminal portion 21 has a long rectangular shape with the first direction x as the longitudinal direction. The first terminal portion 21 includes a first reverse face 21a and a pair of end faces 21b. The first reverse face 21a faces opposite to the first obverse face 11a of the first wiring portion 11. The first reverse face 21a faces the z2 side of the thickness direction z. The first reverse face 21a is exposed from the resin reverse face 42 of the sealing resin 4. The pair of end faces 21b are located at both ends of the first terminal portion 21 in the first direction x. One end face 21b faces the x1 side of the first direction x and is exposed from the first resin side face 431 of the sealing resin 4. The other end face 21b faces the x2 side of the first direction x and is exposed from the second resin side face 432 of the sealing resin 4. Each of the pair of end faces 21b is connected to the first reverse face 21a. The first reverse face 21a and the pair of end faces 21b, which are exposed from the sealing resin 4, may be plated with tin (Sn). Alternatively, a plurality of metals may be applied, for example, nickel (Ni), palladium (Pd), and gold (Au), stacked in this order.

The first wiring portion 11 overlaps with the entirety of the first terminal portion 21 as viewed in the thickness direction z. Hence, the area of the first wiring portion 11 is larger than the area of the first terminal portion 21 as viewed in the thickness direction z. In the semiconductor device A10, the first wiring portion 11 includes a first portion 111 and a second portion 112. The first portion 111 is a part overlapping with the first terminal portion 21 as viewed in the thickness direction z. The second portion 112 is a part not overlapping with the first terminal portion 21 as viewed in the thickness direction z. The first terminal portion 21 is connected to the first portion 111 on the z2 side of the thickness direction z. The second portion 112, which does not overlap with the first terminal portion 21 as viewed in the thickness direction z, includes a first intermediate face 11b. The first intermediate face 11b is located between the first obverse face 11a and the first reverse face 21a in the thickness direction z. Details of the first wiring portion 11 will be described later.

As shown in FIG. 3, the second conductive member 1B is located on the y2 side of the second direction y in the semiconductor device A10. The second conductive member 1B is spaced apart from the first conductive member 1A on the y2 side of the second direction y, and is adjacent to the first conductive member 1A. The second conductive member 1B includes a second wiring portion 12 and a second terminal portion 22, as shown in FIGS. 3, 4, 9, 11, and 12. The second wiring portion 12 includes a part extending in the first direction x and a part extending in the second direction y, and generally has a T-shape as viewed in the thickness direction z. In the present embodiment, the part extending in the first direction x of the second wiring portion 12 extends from the end on the x1 side of the first direction x to the end on the x2 side of the first direction x in the semiconductor device A10. The part extending in the second direction y of the second wiring portion 12 extends from the center of the part extending in the first direction x to the end on the y2 side of the second direction y in the semiconductor device A10. The second wiring portion 12 includes a second obverse face 12a and a second intermediate face 12b. The second obverse face 12a faces the z1 side of the thickness direction z. The second obverse face 12a faces the semiconductor element 3 and supports the semiconductor element 3. The second intermediate face 12b is offset in the z2 side of the thickness direction z with respect to the second obverse face 12a. The second intermediate face 12b faces opposite side of the second obverse face 12a (z2 side of the thickness direction z). The second obverse face 12a and the second intermediate face 12b are covered by the sealing resin 4. The second obverse face 12a, which supports the semiconductor element 3, may be plated with silver.

The second terminal portion 22 is connected to the second wiring portion 12 on the z2 side of the thickness direction z. The second terminal portion 22 extends in the second direction y. The second terminal portion 22 extends in the semiconductor device A10 from the center in the first direction x to the end on the y2 side of the second direction y. As viewed in the thickness direction z, the second terminal portion 22 has a long rectangular shape with the second direction y as the longitudinal direction. The second terminal portion 22 includes a second reverse face 22a and an end face 22b. The second reverse face 22a faces the opposite side of the second obverse face 12a of the second wiring portion 12. The second reverse face 22a faces the z2 side of the thickness direction z. The second reverse face 22a is exposed from the resin reverse face 42 of the sealing resin 4. The end face 22b faces the y2 side of the second direction y. The end face 22b is connected to the second reverse face 22a and is exposed from the fourth resin side face 434 of the sealing resin 4. The second reverse face 22a and the end face 22b, which are exposed from the sealing resin 4, may be plated with tin. Alternatively, a plurality of metals may be applied, for example, nickel, palladium, and gold stacked in this order.

The second wiring portion 12 overlaps with the entirety of the second terminal portion 22 as viewed in the thickness direction z. The second wiring portion 12 includes a protruding portion 121. In the second wiring portion 12, the protruding portion 121 protrudes from the center in the first direction x of the part extending in the first direction x to the y1 side of the second direction y.

As shown in FIG. 3, the pair of third conductive members 1C are located on the y2 side of the second direction y in the semiconductor device A10. The pair of third conductive members 1C are separated from each other in the first direction x. The pair of third conductive members 1C are located on both sides of the first direction x, respectively, sandwiching the second conductive member 1B (second terminal portion 22). One of the third conductive members 1C is located on the x1 side of the first direction x and the other of the third conductive members 1C is located on the x2 side of the first direction x. Each third conductive member 1C includes a third wiring portion 13 and a third terminal portion 23, as shown in FIGS. 3, 4 and 12. The third wiring portion 13 includes a part extending in the first direction x and a part extending in the second direction y, and generally has an L-shape as viewed in the thickness direction z. The third wiring portion 13 includes a third obverse face 13a and a third intermediate face 13b. The third obverse face 13a faces the z1 side of the thickness direction z. The third obverse face 13a faces the semiconductor element 3 and supports the semiconductor element 3. The third intermediate face 13b is offset in the z2 side of the thickness direction z with respect to the third obverse face 13a. The third intermediate face 13b faces the opposite side of the third obverse face 13a (z2 side of the thickness direction z). The third obverse face 13a and the third intermediate face 13b are covered by the sealing resin 4. The third obverse face 13a, which supports the semiconductor element 3, may be plated with silver.

Each third terminal portion 23 is connected to the third wiring portion 13 on the z2 side of the thickness direction z. Each third terminal portion 23 includes a part extending in the first direction x and a part located on the y2 side of the second direction y, these two parts being separated from each other. Each third wiring portion 13 overlaps with the entirety of the relevant third terminal portion 23 as viewed in the thickness direction z. Each third terminal portion 23 includes a third reverse face 23a and end faces 23b and 23c.

The third reverse face 23a faces the opposite side of the third obverse face 13a of the third wiring portion 13. The third reverse face 23a faces the z2 side of the thickness direction z. The third reverse face 23a is exposed from the resin reverse face 42 of the sealing resin 4. The respective end faces 23b face the x1 side or the x2 side of the first direction x. The respective end faces 23b are connected to the third reverse face 23a and are exposed from the first resin side face 431 or the second resin side face 432 of the sealing resin 4. Each end face 23c faces the y2 side of the second direction y. Each end face 23c is connected to the third reverse face 23a and is exposed from fourth resin side face 434 of the sealing resin 4. The third reverse face 23a and the end faces 23b, 23c, which are exposed from the sealing resin 4, may be plated with tin. Alternatively, a plurality of metals may be applied, for example, nickel, palladium, and gold stacked in this order.

As shown in FIG. 3, the plurality of conductive members 1D are located on the y2 side of the second direction y in the semiconductor device A10. In the illustrated example, a pair of conductive members 1D are spaced apart from each other in the first direction x. The pair of conductive members 1D are located on both sides of the first direction X1 respectively, sandwiching the pair of third conductive members 1C. One of the conductive members 1D is located on the x1 side of the first direction x and near a corner on the y2 side of the second direction y, and the other of the conductive members 1D is located on the x2 side of the first direction x and near a corner on the y2 side of the second direction y. Each conductive member 1D includes a wiring portion 14 and a terminal portion 24, as shown in FIGS. 3 and 4. The wiring portion 14 includes an obverse face 14a. The obverse face 14a faces the z1 side of the thickness direction z. The obverse face 14a faces the semiconductor element 3 and supports the semiconductor element 3. The obverse face 14a is covered by the sealing resin 4. The obverse face 14a, which supports the semiconductor element 3, may be plated with silver.

Each terminal portion 24 is connected to the wiring portion 14 on the z2 side of the thickness direction z. Each wiring portion 14 overlaps with the entirety of the relevant terminal portion 24 as viewed in the thickness direction z. Each terminal portion 24 includes a reverse face 24a and end faces 24b, 24c. The reverse face 24a faces opposite to the obverse face 14a of the wiring portion 14. The reverse face 24a faces the z2 side of the thickness direction z. The reverse face 24a is exposed from the resin reverse face 42 of the sealing resin 4. The respective end faces 24b face the x1 side or the x2 side of the first direction x. The respective end faces 24b are connected to the reverse face 24a and are exposed from the first resin side face 431 or the second resin side face 432 of the sealing resin 4. Each end face 24c faces the y2 side of the second direction y. Each end face 24c is connected to the reverse face 24a and is exposed from fourth resin side face 434 of the sealing resin 4. The reverse face 24a and the end faces 24b, 24c, which are exposed from the sealing resin 4, may be plated with tin. Alternatively, a plurality of metals may be applied, for example, nickel, palladium, and gold stacked in this order.

As shown in FIG. 3, the plurality of conductive members 1E are located on the y1 side of the second direction y in the semiconductor device A10. The plurality of conductive members 1E are spaced apart from each other in the first direction x. Each conductive member 1E includes a wiring portion 15 and a terminal portion 25, as shown in FIGS. 3, 4, and 9. Each wiring portion 15 includes an obverse face 15a and an intermediate face 15b. The obverse face 15a faces the z1 side of the thickness direction z. The obverse face 15a faces the semiconductor element 3 and supports the semiconductor element 3. The intermediate face 15b is offset in the z2 side of the thickness direction z with respect to the obverse face 15a. The intermediate face 15b faces the opposite side of the obverse face 15a (z2 side of the thickness direction z). The obverse face 15a and the intermediate face 15b are covered by the sealing resin 4. The obverse face 15a, which supports the semiconductor element 3, may be plated with silver.

Each terminal portion 25 is connected to the wiring portion 15 on the z2 side of the thickness direction z. Each wiring portion 15 overlaps with the entirety of the relevant terminal portion 25 as viewed in the thickness direction z. Each terminal portion 25 includes a reverse face 25a and an The reverse face 25a faces opposite to the end face 25b. obverse face 15a of the wiring portion 15. The reverse face 25a faces the z2 side of the thickness direction z. The reverse face 25a is exposed from the resin reverse face 42 of the sealing resin 4. The end face 25b faces the y1 side of the second direction y. The end face 25b is connected to the reverse face 25a and is exposed from the third resin side face 433 of the sealing resin 4. The reverse face 25a and the end face 25b, which are exposed from the sealing resin 4, may be plated with tin. Alternatively, a plurality of metals may be applied, for example, nickel, palladium, and gold stacked in this order.

As shown in FIG. 3, the plurality of conductive members 1F are disposed in the y1 side of the second direction y with respect to the first conductive member 1A. The conductive members 1F are located between the first conductive member 1A and the conductive members 1E in the second direction y. Certain conductive members 1F are located on the x1 side of the first direction x in the semiconductor device A10. The remainder of the conductive members 1F are located on the x2 side of the first direction x in the semiconductor device A10. Each conductive member 1F includes a wiring portion 16 and a terminal portion 26, as shown in FIGS. 3, 4 and 13. The wiring portion 16 includes an obverse face 16a and an intermediate face 16b. The obverse face 16a faces the z1 side of the thickness direction z. The obverse face 16a faces the semiconductor element 3 and supports the semiconductor element 3. The intermediate face 16b is offset in the z2 side of the thickness direction z with respect to the obverse face 16a. The intermediate face 16b faces the opposite side of the obverse face 16a (z2 side of the thickness direction z). The obverse face 16a and the intermediate face 16b, are covered with the sealing resin 4. The obverse face 16a, which supports the semiconductor element 3, may be plated with silver.

Each terminal portion 26 is connected to the wiring portion 16 on the z2 side of the thickness direction z. Each wiring portion 16 overlaps with the entirety of the relevant terminal portions 26 as viewed in the thickness direction z. Each terminal portion 26 includes a reverse face 26a and an end face 26b. The reverse face 26a faces opposite to the obverse face 16a of the wiring portion 16. The reverse face 26a faces the z2 side of the thickness direction z. The reverse face 26a is exposed from the resin reverse face 42 of the sealing resin 4. The respective end faces 26b face the x1 side or the x2 side of the first direction x. The respective end faces 26b are connected to the reverse face 24a and are exposed from the first resin side face 431 or the second resin side face 432 of the sealing resin 4. The reverse face 26a and the end faces 26b, which are exposed from the sealing resin 4, may be plated with tin. Alternatively, a plurality of metals may be applied, for example, nickel, palladium, and gold stacked in this order.

The semiconductor element 3 is mounted on the first conductive member 1A, the second conductive member 1B, the pair of third conductive members 1C, and the pluralities of conductive members 1D, 1E, 1F, as shown in FIGS. 3 and 9 to 13. The semiconductor element 3 includes an element body 30, a plurality of first electrodes 31, a plurality of electrodes 32, and a plurality of electrodes 33. Although detailed description and illustration are omitted, the element body 30 includes, for example, a semiconductor layer with an internal circuit, the internal circuit with a switching circuit and a controlling circuit electrically connected to the switching circuit. The switching circuit configures, for example, an n-channel MOSFET, and the controlling circuit controls the switching circuit to drive the switching circuit normally.

As shown in FIGS. 9 to 13, in the thickness direction Z, the first electrodes 31, the electrodes 32 and the electrodes 33 are located on the side facing the first obverse face 11a, the second obverse face 12a, the third obverse face 13a and the obverse faces 14a to 16a, respectively. The first electrodes 31, the electrodes 32, and the electrodes 33 are located below the element body 30 (on the z2 side of the thickness direction z). Each of the first electrodes 31 is electrically connected to the first wiring portion 11 (first obverse face 11a) of the first conductive member 1A via the bonding layer 39. Hence, the element body 30 (semiconductor element 3) is electrically connected to the first conductive member 1A. Each of the electrodes 32 is electrically connected to either the second wiring portion 12 (second obverse face 12a) of the second conductive member 1B or the third wiring portion 13 (third obverse face 13a) of each third conductive member 1C via the bonding layer 39. Hence, the element body 30 (semiconductor element 3) is electrically connected to the second conductive member 1B and the pair of third conductive members 1C. Each of the electrodes 33 is electrically connected to one of the wiring portion 14 (obverse face 14a) of each conductive member 1D, the wiring portion 15 (obverse face 15a) of each conductive member 1E and the wiring portion 16 ((obverse face 16a) of each conductive member 1F via the bonding layer 39. Hence, the element body 30 (semiconductor element 3) is electrically connected to the pluralities of conductive members 1D, 1E, 1F. The bonding layer 39 is electrically conductive. In the example represented by the semiconductor device A10, the bonding layer 39 is a metal containing tin and silver or a solder, for example.

Each of the first conductive member 1A, the second conductive member 1B, and the pair of third conductive members 1C is electrically connected to the switching circuit of the semiconductor element 3 (element body 30). Each of the first conductive member 1A, the second conductive member 1B, and the pair of third conductive members 1C provides a path for the main circuit current to be switched by the semiconductor element 3 (aforementioned switching circuit), for example. Each of the pluralities of conductive members 1D, 1E, 1F receives electric power (voltage) to drive the controlling circuit or electrical signals to be transmitted to the controlling circuit, for example.

The first wiring portion 11 will be described with reference to FIGS. 14 and 15.

As described above, the first wiring portion 11 includes the first portion 111 and the second portion 112. The first portion 111 is a part overlapping with the first terminal portion 21 as viewed in the thickness direction z, and the second portion 112 is a part not overlapping with the first terminal portion 21 as viewed in the thickness direction z. Each of the first portion 111 and the first terminal portion 21 extends in the first direction x.

In the present embodiment, the second portion 112 includes a first extending portion 113 and a second extending portion 114. The first extending portion 113 extends from the first portion 111 to the y1 side of the second direction y. The second extending portion 114 extends from the first portion 111 to the y2 side of the second direction y. The first extending portion 113 has a length along the second direction y at the x1 side or the x2 side of the first direction x that is smaller than a length along the second direction y at the center of the first direction x. This is due to avoid interference between the first wiring portion 11 and its adjacent conductive members 1F (wiring portion 16) on the y1 side of the second direction y (see FIG. 3).

In the present embodiment, the first electrodes 31 are arranged along the first direction x. The first electrodes 31 overlap with the first portion 111 as viewed in the thickness direction z. More specifically, a part of each first electrode 31 overlaps with the first portion 111, and the remainder of each first electrode 31 overlaps with the first extending portion 113 (second portion 112) as viewed in the thickness direction z.

The first extending portion 113 (second portion 112) includes a first region 112A, which is a trapezoid region extending in the first direction x as viewed in the thickness direction z that overlaps with the first electrodes 31 and is connected to the first portion 111. The first region 112A is sum of a region with the first direction x as the longitudinal direction in which the first electrodes 31 are arranged and a region between each end of the region with the first direction x as the longitudinal direction and the most distant position from the boundary of the first extending portion 113 (second portion 112) and the first portion 111.

The first extending portion 113 includes a first inner portion 113A and a first outer portion 113B. The first inner portion 113A is connected to the first portion 111, and forms the first region 112A. The first outer portion 113B is connected to the first inner portion 113A, and is offset in the y1 side of the second direction y with respect to the first inner portion 113A.

As shown in FIGS. 14 and 15, a first dimension L1, which is a length of the first outer portion 113B along the second direction y, is larger than a second dimension L2, which is a length of the first terminal portion 21 along the second direction y. For example, the first dimension L1 is 1.5 to 2.5 times the second dimension L2.

The second extending portion 114 includes a recess 114a. The recess 114a is recessed to the y1 side of the second direction y more than other parts at the center of the second extending portion 114 in the first direction x. The recess 114a is provided corresponding to the protruding portion 121 of the second wiring portion 12 in the second conductive member 1B. The recess 114a overlaps with entirety of the protruding portion 121 as viewed in the second direction y.

The part necessary for a path for electrical current between the semiconductor element 3 and the first terminal portion 21 (hereinafter referred to as a “necessary portion” as appropriate) in the first wiring portion 11 of the first conductive member 1A includes the first portion 111, which overlaps with the first terminal portion 21 as viewed in the thickness direction z, and the first region 112A. In FIG. 14, the entirety of the first wiring portion 11 is shown with hatching that diagonally falling to the right. Also, the necessary portion for flow of electrical current in the first wiring portion 11 (the first portion 111 and the first region 112A) are shown with hatching that diagonally rising to the right. In the example shown in FIG. 14, as viewed in the thickness direction z, the edge of the first region 112A on the y1 side of the second direction y corresponds to line segments extending in the first direction x tangential to the ends at the y1 side of the second direction y of the first electrodes 31, which are arranged in the first direction x.

As viewed in the thickness direction z, the ratio of a second area S2 (sum of the area of the first portion 111 and the area of the first region 112A), which is the area of the necessary portion of the path for electrical current (the first portion 111 and the first region 112A) relative to a first area S1, which is the area of the entirety of the first wiring portion 11, is 60% or less, for example. The ratio of the second area S2 to the first area S1 is preferably 20% to 50%. In the present embodiment shown in FIG. 14, the ratio of the second area S2 to the first area S1 is 42.2%.

In the present embodiment, a part of the first wiring portion 11 that is unnecessary as the path for electrical current between the semiconductor element 3 and the first terminal portion 21 (hereinafter referred to as the “unnecessary portion” as appropriate) is other than the necessary portion (the first portion 111 and the first region 112A). Specifically, the unnecessary portion is the second extending portion 114 and a part of the first extending portion 113 (mainly the outer first portion 113B) other than the first region 112A (inner first portion 113A). The ratio of the area of the unnecessary portion of the path for electrical current is at least 40%, and preferably 50% to 80% in the first wiring portion 11.

Next, the effects of the present embodiment will be described.

The semiconductor device A10 includes the first conductive member 1A, the semiconductor element 3 and the sealing resin 4. The first conductive member 1A includes the first wiring portion 11 and the first terminal portion 21 connected to the first wiring portion 11 on the z2 side of the thickness direction z. The first wiring portion 11 includes the first obverse face 11a facing the z1 side of the thickness direction z, and the first terminal portion 21 includes the first reverse face 21a facing the z2 side of the thickness direction z, the first reverse face 21a being exposed from the resin reverse face 42 of the sealing resin 4. The semiconductor element 3 includes the plurality of first electrodes 31 provided on the side facing the first obverse face 11a in the thickness direction z, the plurality of first electrodes 31 being electrically connected to the first obverse face 11a. The first wiring portion 11 includes the first portion 111 overlapping with the first terminal portion 21 as viewed in the thickness direction z, and a second portion 112 not overlapping with the first terminal portion 21 as viewed in the thickness direction z. As viewed in the thickness direction z, the ratio of the second area S2 (sum of the area of the first portion 111 and the area of the first region 112A), which is the area of the necessary portion of the path for electrical current, relative to the first area S1, which is the area of the entirety of the first wiring portion 11, is 60% or less. Such a configuration results in that the ratio of the unnecessary portion of the path for electrical current is 40% or more in the first wiring portion 11. The increased unnecessary the path for electrical current in the first wiring portion 11 in this manner improves the electrical characteristics of the semiconductor device A10 such as reducing the impedance between the semiconductor element 3 and the first terminal portion 21.

The ratio of the area of the necessary portion of the path for electrical current (second area S2) to the area of the first wiring portion 11 (first area S1) is 20% to 50%. In this manner, the ratio of the area of the unnecessary portion of the path for electrical current is 50% to 80% in the first wiring portion 11. Such a configuration reduces the excessively large ratio of the unnecessary portion in the first wiring portion 11, which is desirable for downsizing the semiconductor device A10.

The first extending portion 113 includes the first inner portion 113A and the first outer portion 113B. The first inner portion 113A is connected to the first portion 111 and forms the first region 112A. The first outer portion 113B is a portion connected to the first inner portion 113A and is offset in the y1 side of the second direction y with respect to the first inner portion 113A. The first dimension L1, which is the length of the first outer portion 113B along the second direction y, is larger than the second dimension L2, which is the length of the first terminal portion 21 along the second direction y. Such a configuration may efficiently reduce the ratio of the area of the necessary portion of the path for electrical current (second area S2) to the area of the first wiring portion 11 (first area S1). In other words, the ratio of the area of the unnecessary portion of the path for electrical current in the first wiring portion 11 may be efficiently increased. Therefore, this structure is suitable for improving electrical characteristics of the semiconductor device A10.

The first dimension L1, which is the length of the first outer portion 113B along the second direction y, is 1.5 to 2.5 times the second dimension L2, which is the length of the first terminal portion 21 along the second direction y. The increased length of the first extending portion 113 in the second direction y (dimension 1 L1) in this manner improves the effect of preventing the sealing resin 4 from peeling off from the first conductive member 1A, as well as improving the electrical characteristics of the semiconductor device A10 described above.

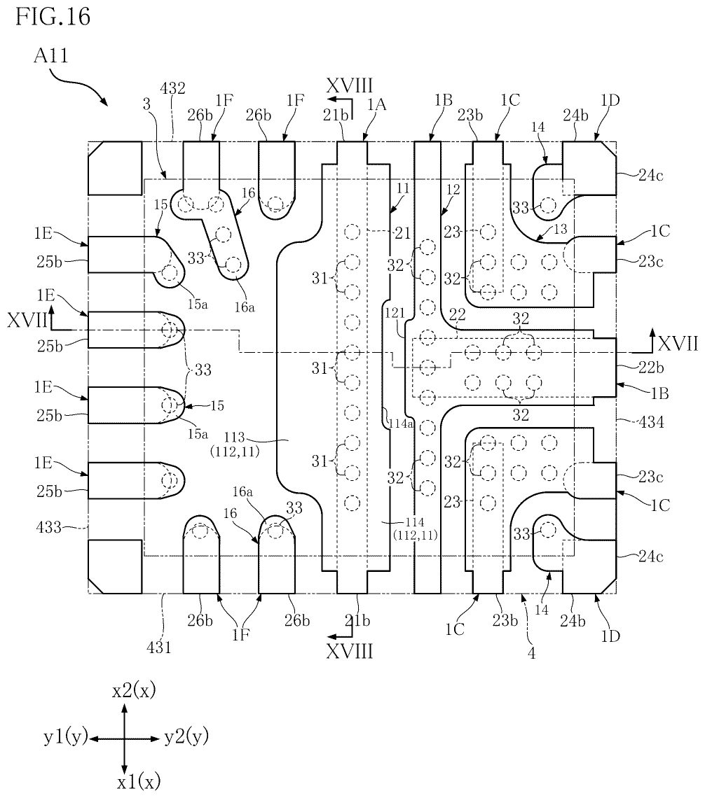

FIGS. 16 to 25 illustrate variations of the semiconductor device of the present disclosure. In these figures, elements identical or similar to the above embodiment are denoted by the same reference signs as those of the above embodiment, and redundant explanations are omitted. Various parts of embodiments may be selectively used in any appropriate combination as long it as is technically compatible.

### First Variation of the First Embodiment

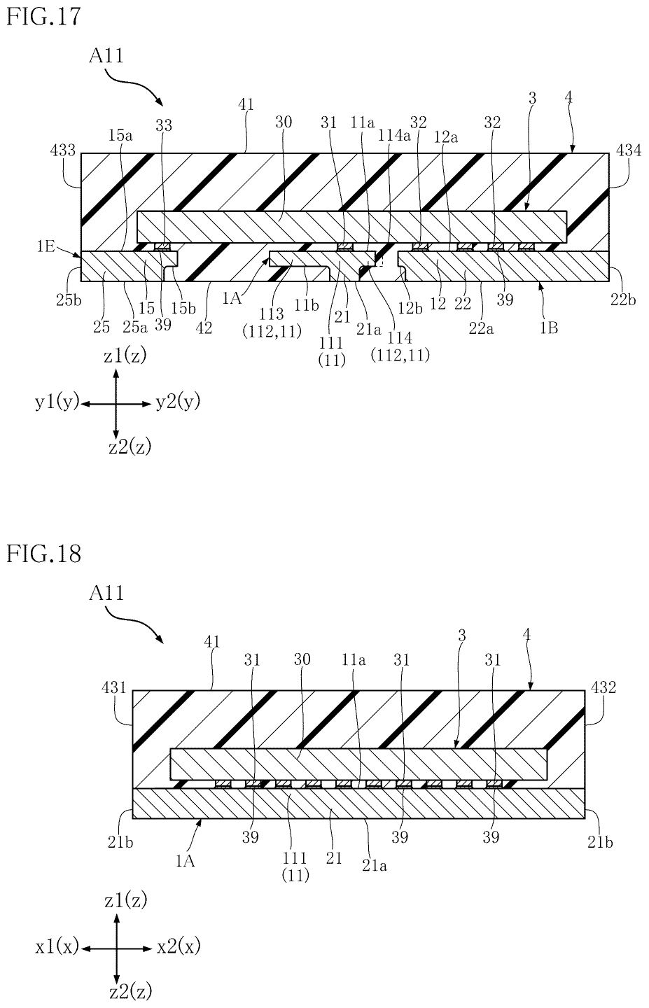

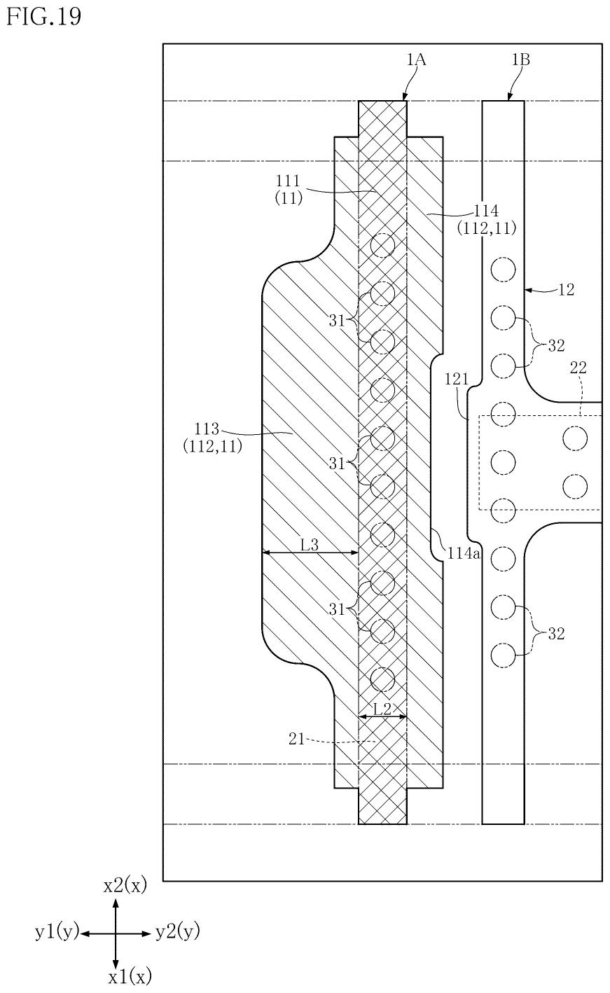

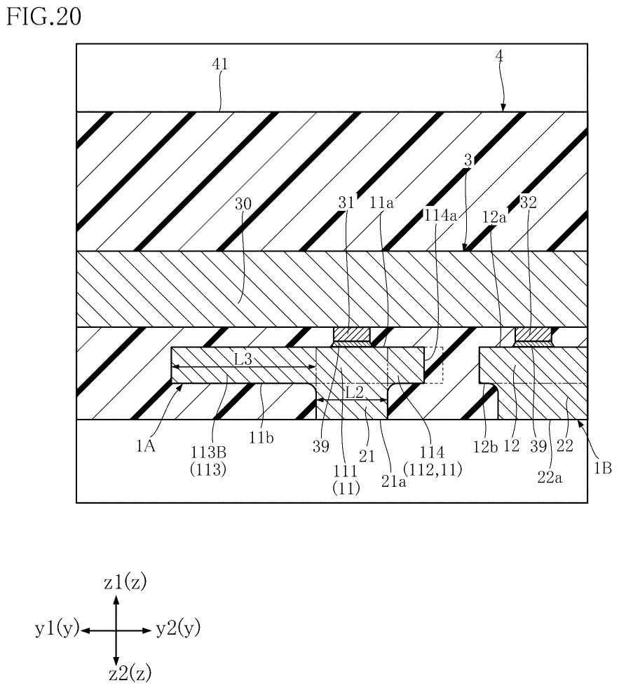

FIGS. 16 to 20 show a semiconductor device A11 according to a first variation of the first embodiment. FIG. 16 is a plan view similar to FIG. 3, showing the semiconductor device A11. In FIG. 16, the semiconductor element 3 and the sealing resin 4 are omitted for the sake of understanding. In FIGS. 16 to 20, the omitted semiconductor element 3 and sealing resin 4 are shown as imaginary lines (two dotted lines), respectively. FIG. 17 is a cross-sectional view taken along a line XVII-XVII in FIG. 16. FIG. 18 is a cross-sectional view taken along a line XVIII-XVIII in FIG. 16. FIG. 19 is a partially enlarged view of FIG. 16. FIG. 20 is a partially enlarged view of FIG. 17.

The semiconductor device A11 of the present variation differs from the semiconductor device A10 of the above embodiment in the arrangement of the plurality of first electrodes 31. Accordingly, the configuration of the first extending portion 113 differs from the above embodiment. In the semiconductor device A11, the first electrodes 31 are arranged along the first direction x as with the above embodiment. On the other hand, in this variation, all of the first electrodes 31 overlap with the first portion 111 as viewed in the thickness direction z. Hence, none of the first electrodes 31 overlaps with the first extending portion 113 (second portion 112) as viewed in the thickness direction z. As a result, the first extending portion 113 (second portion 112) does not include the first region 112A. Also, the first extending portion 113 does not have distinction between the first inner portion 113A and the first outer portion 113B as in the above embodiment.

As shown in FIGS. 19 and 20, a dimension L3, which is the length of the first extending portion 113 along the second direction y, is larger than the dimension L2, which is the length of the first terminal portion 21 along the second direction y. The dimension L3 is two to three times the second dimension L2, for example.

In the first wiring portion 11 of the first conductive member 1A, the necessary portion of the path for electrical current between the semiconductor element 3 and the first terminal portion 21 is the first portion 111 overlapping with the first terminal portion 21 as viewed in the thickness direction z. In FIG. 19, the entirety of the first wiring portion 11 is shown with hatching that diagonally falling to the right. Also, the necessary portion of the path for electrical current (first portion 111) of the first wiring portion 11 is shown with hatching that diagonally rising to the right.

As viewed in the thickness direction z, the ratio of the second area S2 (area of the first portion 111), which is the area of the necessary portion of the path for electrical current (the first portion 111), relative to the first area S1, which is the area of the entirety of the first wiring portion 11 is 60% or less, for example. The ratio of the second area S2 to the first area S1 is preferably 20% to 50%. In this variation shown in FIG. 19, the ratio of the second area S2 to the first area S1 is 34.6%.

In the present variation, the unnecessary portion of the path for electrical current between the semiconductor element 3 and the first terminal portion 21 is other than the necessary portion (first portion 111) in the first wiring portion 11. Specifically, the unnecessary portion is the second portion 112 (first extending portion 113 and second extending portion 114). The ratio of the area of the unnecessary portion of the path for electrical path in the first wiring portion 11 is 40% or more, and preferably 50% to 80%.

In the present variation of the semiconductor device A11, the first wiring portion 11 of the first conductive member 1A includes the first portion 111 overlapping with the first terminal portion 21 as viewed in the thickness direction z, and the second portion 112 not overlapping with the first terminal portion 21 as viewed in the thickness direction z. The ratio of the second area S2 (area of the first portion 111), which is the area of the necessary portion of the path for electrical current, relative to the first area S1, which is the area of the first wiring portion 11, is 60% or less, as viewed in the thickness direction z. Such a configuration results in that the ratio of the unnecessary portion of the path for electrical current is 40% or more in the first wiring portion 11. The increased unnecessary portion of the path for electrical current in the first wiring portion 11 in this manner improves the electrical characteristics of the semiconductor device A11 such as reducing the impedance between the semiconductor element 3 and the first terminal portion 21.

The ratio of the area of the necessary portion of the path for electrical current (second area S2) to the area of the first wiring portion 11 (first area S1) is 20% to 50%. In this manner, the ratio of the area of the unnecessary portion of the path for electrical current is 50% to 80% in the first wiring portion 11. Such a configuration reduces the excessively large ratio of the unnecessary portion in the first wiring portion 11, which is desirable for downsizing the semiconductor device A11.

The dimension L3, which is the length of the first extending portion 113 along the second direction y, is larger than the second dimension L2, which is the length of the first terminal portion 21 along the second direction y. Such a configuration may effectively reduce the ratio of the area of the necessary portion of the path for electrical current (second area S2) to the area of the first wiring portion 11 (first area S1). In other words, the ratio of the area of the unnecessary portion of the path for electrical current in the first wiring portion 11 may be efficiently increased. Therefore, the semiconductor device A11 has the structure suitable for improving its electrical characteristics.

The dimension L3, which is the length of the first extending portion 113 along the second direction y, is two to three the second dimension L2, which is the length of the first terminal portion 21 along the second direction y. The increased length of the first extending portion 113 in the second direction y (dimension L3) in this manner improves the effect of preventing the sealing resin 4 from peeling off from the first conductive member 1A, as well as improving the electrical characteristics of the semiconductor device A11 described above.

### Second Variation of the First Embodiment

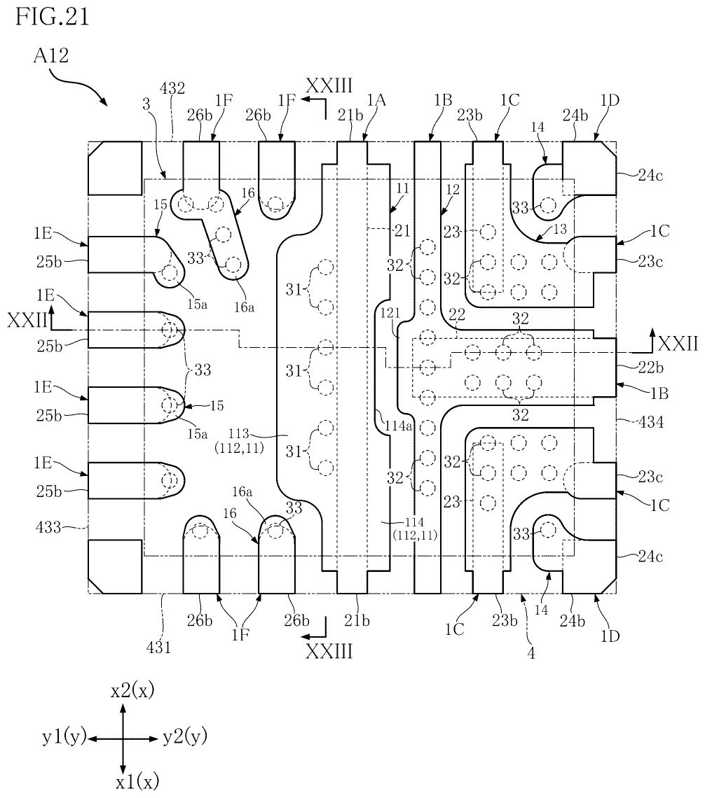

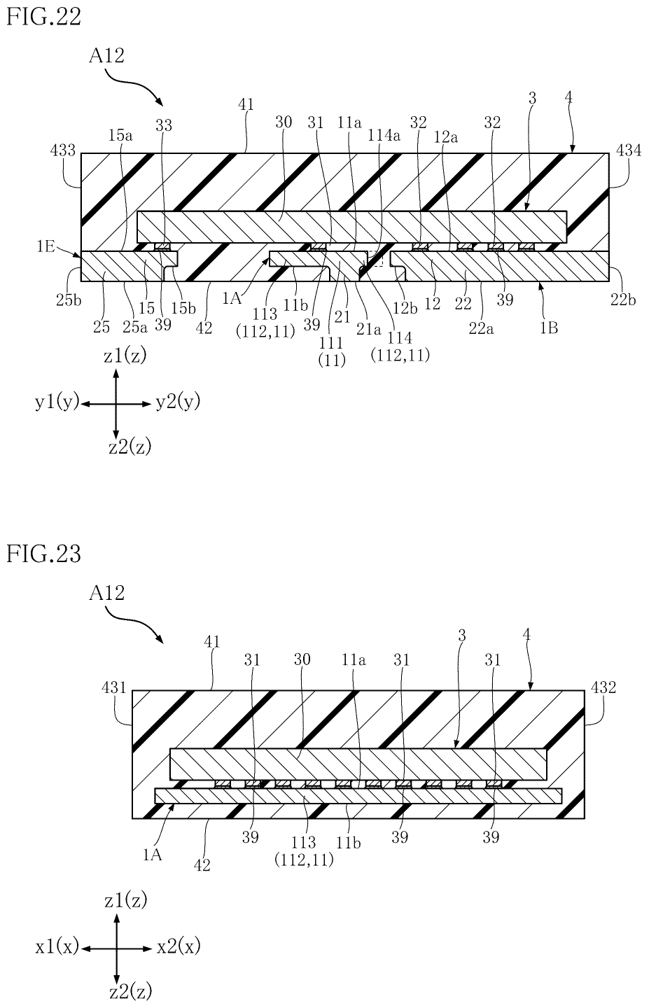

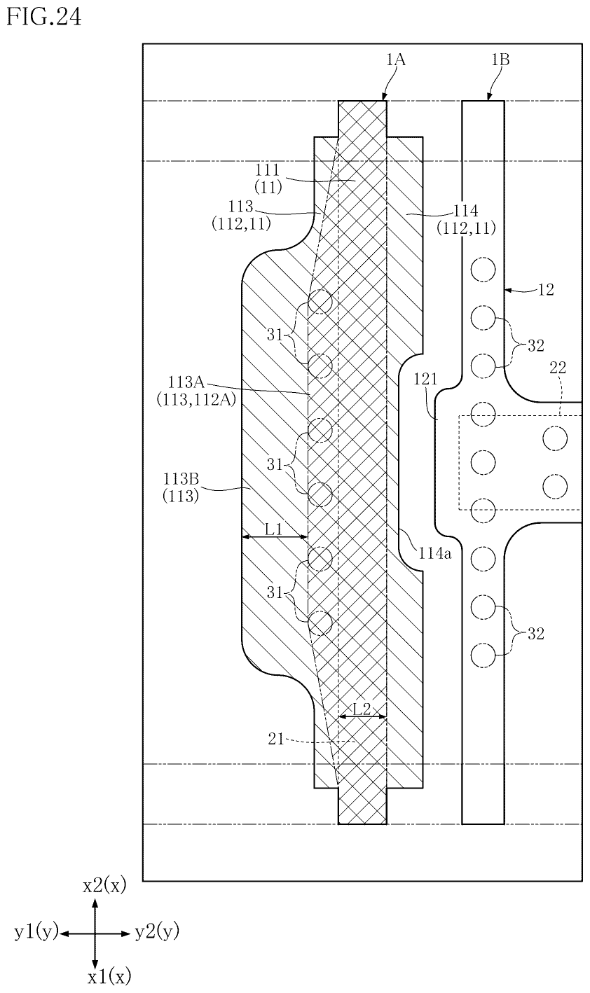

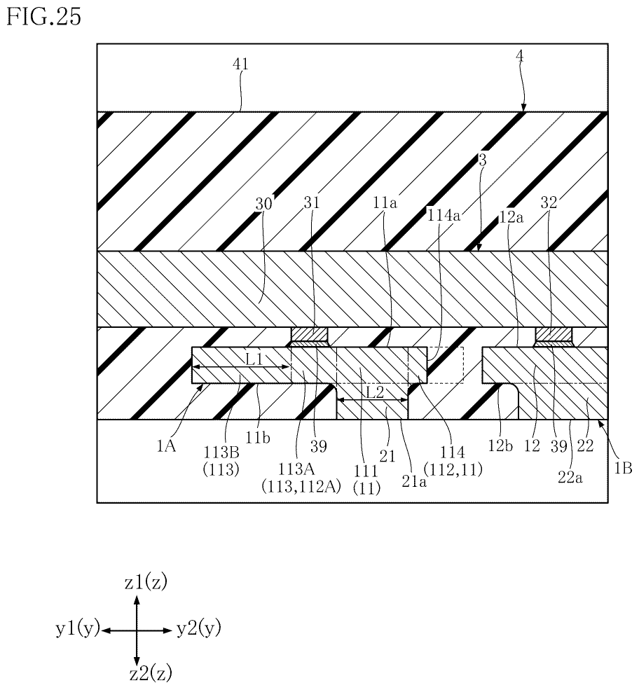

FIGS. 21 to 25 show a semiconductor device A12 according to a second variant of the first embodiment. FIG. 21 is a plan view similar to FIG. 3, showing the semiconductor device A12. In FIG. 21, the semiconductor element 3 and the sealing resin 4 are omitted, for the sake of understanding. In the same figures, the omitted semiconductor element 3 and sealing resin 4 are shown as imaginary lines (two dotted lines), respectively. FIG. 22 is a cross-sectional view taken along a line XXII-XXII in FIG. 21. FIG. 23 is a cross-sectional view taken along a line XXIII-XXIII in FIG. 21. FIG. 24 is a partially enlarged view of FIG. 21. FIG. 25 is a partially enlarged view of FIG. 22.

The semiconductor device A12 of the present variation differs from the semiconductor device A10 of the above embodiment in the arrangement of the plurality of first electrodes 31. In the semiconductor device A12, the first electrodes 31 are arranged along the first direction x as with the above embodiment. On the other hand, in the present variation, all of the first electrodes 31 overlap with the first extending portion 113 (second portion 112) as viewed in the thickness direction Z. In addition, in the present variation, the number of first electrodes 31 arranged along the first direction x is less than that in the semiconductor device A10, so that the spacing between adjacent first electrodes 31 in the first direction x is larger than that in the semiconductor device A10.

In the present variation, as with the semiconductor device A10, the first region 112A is the trapezoidal region in the first extending portion 113 (second portion 112) as viewed in the thickness direction z that overlaps with the first electrodes 31 and is connected to the first portion 111. The first region 112A is sum of the region with the first direction x as the longitudinal direction in which the first electrodes 31 are arranged and the region between each end of the region with the first direction x as the longitudinal direction and the most distant position from the boundary of the first extending portion 113 (second portion 112) and the first portion 111.

In the present variation, the first extending portion 113 includes a first inner portion 113A and a first outer portion 113B, as with the semiconductor device A10. The first inner portion 113A is connected to the first portion 111 and forms the first region 112A. The first outer portion 113B is connected to the first inner portion 113A and is offset in the y1 side of the second direction y with respect to the first inner portion 113A.

As shown in FIGS. 24 and 25, the first dimension L1, which is the length of the first outer portion 113B along the second direction y, is larger than the second dimension L2, which is the length of the first terminal portion 21 along the second direction y. The first dimension L1 is 1.5 to 2.5 times the second dimension L2, for example.

The necessary portion of the path for electrical current between the semiconductor element 3 and the first terminal portion 21 in the first wiring portion 11 of the first conductive member 1A is the first portion 111 and the first region 112A overlapping with the first terminal portion 21 as viewed in the thickness direction z. In FIG. 24, the entirety of the first wiring portion 11 is shown with hatching that diagonally falling to the right. In addition, the necessary portion of the path for electrical current in the first wiring portion 11 (first portion 111 and first region 112A) are shown with hatching that diagonally rising to the right. In the example shown in FIG. 24, as viewed in the thickness direction z, the edge of the first region 112A on the y1 side of the second direction y corresponds to line segments extending in the first direction x tangential to the ends at the y1 side of the second direction y of the first electrodes 31, which are arranged in the first direction x.

As viewed in the thickness direction z, the ratio of the second area S2 (sum of the area of the first portion 111 and the first region 112A), which is the area of the necessary portion of the path for electrical current (the first portion 111 and the first region 112A), relative to the first area S1, which is the area of the entirety of the first wiring portion 11 is 60% or less, for example. The ratio of the second area S2 to the first area S1 is preferably 20% to 50%.

In this variation shown in FIG. 24, the ratio of the second area S2 to the first area S1 is 49.6%.

In the present variation, the unnecessary portion of the path for electrical current between the semiconductor element 3 and the first terminal portion 21 is other than the necessary portion (first portion 111 and the first region 112A) in the first wiring portion 11. Specifically, the unnecessary portion is the portion other than the first region 112A (mainly the first inner portion 113A) in the first extending portion 113 (mainly the first outer portion 113B) and the second extending portion 114. The ratio of the area of the unnecessary portion of the path for electrical path in the first wiring portion 11 is 40% or more, and preferably 50% to 80%.

In the present variation of the semiconductor device A12, the first wiring portion 11 of the first conductive member 1A includes the first portion 111 overlapping with the first terminal portion 21 as viewed in the thickness direction z, and the second portion 112 not overlapping with the first terminal portion 21 as viewed in the thickness direction z.

As viewed in the thickness direction z, the ratio of the second area S2 (sum of the area of the first portion 111 and the first region 112A), which is the area of the necessary portion of the path for electrical current, relative to the first area S1, which is the area of the entirety of the first wiring portion 11 is 60% or less. Such a configuration results in that the ratio of the unnecessary portion of the path for electrical current is 40% or more in the first wiring portion 11. The increased unnecessary portion of the path for electrical current in the first wiring portion 11 in this manner improves the electrical characteristics of the semiconductor device A12 such as reducing the impedance between the semiconductor element 3 and the first terminal portion 21.

The ratio of the area of the necessary portion of the path for electrical current (second area S2) to the area of the first wiring portion 11 (first area S1) is 20% to 50%. In this manner, the ratio of the area of the unnecessary portion of the path for electrical current is 50% to 80% in the first wiring portion 11. Such a configuration reduces the excessively large ratio of the unnecessary portion in the first wiring portion 11, which is desirable for downsizing the semiconductor device A12. Otherwise, the semiconductor device A12 has the same effects as the semiconductor device A10 of the above embodiment.

The semiconductor devices according to the present disclosure are not limited to the embodiments described above. The specific configuration of each part of a semiconductor device according to the present disclosure may suitably be designed and changed in various manners.

In the above embodiment, the case is described in which the first conductive member 1A, the second conductive member 1B, the pair of third conductive members 1C, and the pluralities of conductive members 1D, 1E, 1F are each formed from a lead, but the present disclosure is not limited thereto. The first conductive member 1A, the second conductive member 1B, the pair of third conductive members 1C, and the pluralities of conductive members 1D, 1E, 1F may be configured, for example, by metal plating in a desired shape.

The present disclosure includes the embodiments described in the following clauses.

### Clause 1

A semiconductor device comprising:

a first conductive member including:
a first wiring portion with a first obverse face facing one side of a thickness direction, and
a first terminal portion connected to the first wiring portion and including a first reverse face facing another side of the thickness direction;

a semiconductor element located in a side facing the first obverse face in the thickness direction and including at least one electrode electrically connected to the first obverse face; and

a sealing resin covering a part of the first wiring portion, a part of the first terminal portion, and the semiconductor element, and including a resin reverse face facing another side of the thickness direction,

wherein the first reverse face is exposed from the resin reverse face,

the first wiring portion includes a first portion overlapping with the first terminal portion as viewed in the thickness direction and a second portion not overlapping with the first terminal portion as viewed in the thickness direction,

the second portion includes a first intermediate face located between the first obverse face and the first reverse face in the thickness direction and facing another side of the thickness direction,

the first intermediate face is covered by the sealing resin,

the first wiring portion includes a first area as viewed in the thickness direction,

the second portion includes a first region between a part overlapping with the at least one electrode and a part connected to the first portion as viewed in the thickness direction,

the first portion and the first region constitute a second area, and

the ratio of the second area to the first area is 60% or less.

### Clause 2

The semiconductor device according to clause 1, wherein the ratio of the second area to the first area is 20% to 50%.

### Clause 3

The semiconductor device according to clause 1 or 2, wherein the first portion and the first terminal portion extend in a first direction orthogonal to the thickness direction.

### Clause 4

The semiconductor device according to clause 3, wherein the at least one electrode comprises a plurality of electrodes that are arranged along the first direction.

### Clause 5

The semiconductor device according to clause 4, wherein at least a part of each of the plurality of electrodes overlaps with the first portion as viewed in the thickness direction.

### Clause 6

The semiconductor device according to clause 4 or 5, wherein the second portion includes a first extending portion extending from the first portion to one side of a second direction orthogonal to the thickness direction and the first direction.

### Clause 7

The semiconductor device according to clause 6, wherein at least one of the plurality of the electrodes overlaps with the first portion and the first extending portion as viewed in the thickness direction.

### Clause 8

The semiconductor device according to clause 6 or 7, wherein the first extending portion includes a first inner portion connected to the first portion and constituting at least a part of the first region, and a first outer portion connected to the first inner portion and offset in one side of the second direction with respect to the first inner portion,
a first dimension, which is a length of the first outer portion along the second direction, is larger than a second dimension, which is a length of the first terminal portion along the second direction.

### Clause 9

The semiconductor device according to clause 8, wherein the first dimension is 1.5 to 2.5 times the second dimension.

### Clause 10

The semiconductor device according to any one of clauses 6 to 9, wherein the second portion includes a second extending portion extending from the first portion to another side of the second direction.

### Clause 11

The semiconductor device according to clause 10, further comprising a second conductive member including a second wiring portion with a second obverse face facing the one side of the thickness direction, and a second terminal portion with a second reverse face connected to the second wiring portion on another side of the thickness direction and facing another side of the thickness direction,

wherein the second conductive member is disposed in another side of the second direction with respect to the first conductive member.

### Clause 12

The semiconductor device according to clause 11, wherein the second wiring portion includes a protruding portion protruding to the one side of the second direction,

the second extending portion overlaps with the entirety of the protruding portion as viewed in the second direction and includes a recess recessed into the one side of the second direction.

### Clause 13

The semiconductor device according to any one of clauses 1 to 12, wherein the first conductive member contains copper. Clause 14.

The semiconductor device according to clause 13, wherein the first conductive member is formed from a lead.

### REFERENCE NUMERALS

A10, A11, A12: Semiconductor device
1A: First conductive member
1B: Second conductive member
1C: Third conductive member
1D, 1E, 1F: Conductive member
11: First wiring portion 11a: First obverse face
11b: First intermediate face 111: First portion
112: Second portion 112A: First region
113: First extending portion 113A: First inner portion
113B: First outer portion 114: Second extending portion
114a: Recess
12: Second wiring portion
12b: Second intermediate face 12a: Second obverse face
13: Third wiring portion 121: Protruding portion
13a: Third obverse face 13b: Third intermediate face
14, 15, 16: Wiring portion 14a, 15a, 16a: Obverse face
21: First terminal portion 15b, 16b: Intermediate face
21a: First reverse face 22: Second terminal portion
23: Third terminal portion 22a: Second reverse face
23a: Third reverse face 24, 25, 26: Terminal portion
24a, 25a, 26a: Reverse face
21b, 22b, 23b, 23c, 24b, 24c, 25b, 26b: End face
3: Semiconductor element 30: Element body
31: First electrode 32, 33: Electrode
39: Bonding layer 4: Sealing resin
41: Resin obverse face 42: Resin reverse face
431: First resin side face 432: Second resin side face
433: Third resin side face 434: Fourth resin side face
L1: First dimension L2: Second dimension
L3: Dimension S1: First area S2: Second area
x: First direction y: Second direction
z: Thickness direction

1. A semiconductor device comprising:
a first conductive member including:
a first wiring portion with a first obverse face facing one side of a thickness direction, and
a first terminal portion connected to the first wiring portion and including a first reverse face facing another side of the thickness direction;
a semiconductor element located in a side facing the first obverse face in the thickness direction and including at least one electrode electrically connected to the first obverse face; and
a sealing resin covering a part of the first wiring portion, a part of the first terminal portion, and the semiconductor element, and including a resin reverse face facing another side of the thickness direction,
wherein the first reverse face is exposed from the resin reverse face,
the first wiring portion includes a first portion overlapping with the first terminal portion as viewed in the thickness direction and a second portion not overlapping with the first terminal portion as viewed in the thickness direction,
the second portion includes a first intermediate face located between the first obverse face and the first reverse face in the thickness direction and facing another side of the thickness direction,
the first intermediate face is covered by the sealing resin,
the first wiring portion includes a first area as viewed in the thickness direction,
the second portion includes a first region between a part overlapping with the at least one electrode and a part connected to the first portion as viewed in the thickness direction,
the first portion and the first region constitute second area, and
the ratio of the second area to the first area is 60% or less.

2. The semiconductor device according to claim 1, wherein the ratio of the second area to the first area is 20% to 50%.

3. The semiconductor device according to claim 1, wherein the first portion and the first terminal portion extend in a first direction orthogonal to the thickness direction.

4. The semiconductor device according to claim 3, wherein the at least one electrode comprises a plurality of electrodes that are arranged along the first direction.

5. The semiconductor device according to claim 4, wherein at least a part of each of the plurality of electrodes overlaps with the first portion as viewed in the thickness direction.

6. The semiconductor device according to claim 4, wherein the second portion includes a first extending portion extending from the first portion to one side of a second direction orthogonal to the thickness direction and the first direction.

7. The semiconductor device according to claim 6, wherein at least one of the plurality of the electrodes overlaps with the first portion and the first extending portion as viewed in the thickness direction.

8. The semiconductor device according to claim 7, wherein the first extending portion includes a first inner portion connected to the first portion and constituting at least a part of the first region, and a first outer portion connected to the first inner portion and offset in one side of the second direction with respect to the first inner portion, a first dimension, which is a length of the first outer portion along the second direction, is larger than a second dimension, which is a length of the first terminal portion along the second direction.

9. The semiconductor device according to claim 8, wherein the first dimension is 1.5 to 2.5 times the second dimension.

10. The semiconductor device according to claim 6, wherein the second portion includes a second extending portion extending from the first portion to another side of the second direction.

11. The semiconductor device according to claim 10, further comprising a second conductive member including a second wiring portion with a second obverse face facing the one side of the thickness direction, and a second terminal portion with a second reverse face connected to the second wiring portion on another side of the thickness direction and facing another side of the thickness direction,
wherein the second conductive member is disposed in another side of the second direction with respect to the first conductive member.

12. The semiconductor device according to claim 11, wherein the second wiring portion includes a protruding portion protruding to the one side of the second direction,
the second extending portion overlaps with the entirety of the protruding portion as viewed in the second direction and includes a recess recessed into the one side of the second direction.

13. The semiconductor device according to claim 1, wherein the first conductive member contains copper.

14. The semiconductor device according to claim 13, wherein the first conductive member is formed from a lead.
